(19) United States
(12) Patent Application Publication
(10) Pub. No.: US 2014/0048130 A1
(43) Pub. Date: Feb. 20, 2014

(54) CRYSTALLINE SILICON SOLAR CELL WATER, AND SOLAR CELL EMPLOYING THE SAME

(71) Applicant: INDUSTRIAL TECHNOLOGY RESEARCH INSTITUTE, Hsinchu (TW)

(72) Inventor: Wen-Jong LIH, Hsinchu City (TW)

(73) Assignee: INDUSTRIAL TECHNOLOGY RESEARCH INSTITUTE, Hsinchu (TW)

(21) Appl. No.: 13/968,851

(22) Filed: Aug. 16, 2013

(30) Foreign Application Priority Data
Aug. 17, 2012 (TW) 101130051
Aug. 17, 2012 (TW) 101130052
Aug. 17, 2012 (TW) 101130053
Aug. 17, 2012 (TW) 101130054

(51) Int. Cl. H01L 31/032; H01L 31/0224; H01L 31/0368

(52) U.S. Cl. CPC H01L 31/032; H01L 31/0368; H01L 31/022425
USPC 136/256; 136/261; 136/258

(57) ABSTRACT

The disclosure provides a crystalline silicon solar cell wafer, and a solar cell employing the same. The crystalline silicon solar cell wafer, having an edge isolation structure, includes: a crystalline silicon substrate having a first surface, a second surface, and a side surface, and an insulating layer formed merely on the side surface of the crystalline silicon substrate.

### CROSS REFERENCE TO RELATED APPLICATIONS

The present application is based on, and claims priority from, Taiwan Application Serial Number 101130051, filed Aug. 17, 2012, Taiwan Application Serial Number 101130052, filed Aug. 17, 2012, Taiwan Application Serial Number 101130053, filed Aug. 17, 2012, and Taiwan Application Serial Number 101130054, filed Aug. 17, 2012, the disclosure of which is hereby incorporated by reference herein in its entirety.

### TECHNICAL FIELD

The disclosure relates to a crystalline silicon solar cell wafer, and a solar cell employing the same.

### BACKGROUND

The negative effects of ecological problems resulting from fossil fuels such as petroleum and coal are well-known. Consequently, there are growing demands for clean energy. Among the various alternative energy sources, solar cells are expected to replace fossil fuels as a new energy source, because it provides clean energy without depletion and is easily handled.

In the fabrication of conventional solar cells, in order to prevent n-type electrodes from contacting p-type electrodes at the edge region of a wafer, an edge isolation process is performed. The power generation area of the solar cell, however, is reduced after the edge isolation process. Further, the edge isolation process is performed by laser cutting or acid/base etching, in general, resulting in high manufacturing costs (such as the need for an expensive laser apparatus) and environmental problems (such as waste fluid from the etching process).

Therefore, it is desirable to devise a novel method for fabricating solar cells that improves upon the aforementioned problems.

### SUMMARY

An exemplary embodiment of the disclosure provides a crystalline silicon solar cell wafer, including a crystalline silicon substrate, wherein the crystalline silicon substrate has a first surface, a second surface, and a side surface, and an insulating layer formed merely on the side surface of the crystalline silicon substrate.

Another exemplary embodiment of the disclosure provides a crystalline silicon solar cell, including: a crystalline silicon substrate, wherein the crystalline silicon substrate has a first surface, a second surface, and a side surface, wherein the crystalline silicon substrate has a first conductivity type; an insulating layer formed merely on the side surface of the crystalline silicon substrate; an anti-reflection layer disposed on the first surface of the crystalline silicon substrate; a doping layer disposed between the first surface of the crystalline silicon substrate and the anti-reflection layer, wherein the doping layer has a second conductivity type; a first electrode disposed on the anti-reflection layer, wherein the first electrode passes through the anti-reflection layer to electrically contact with the doping layer; and a second electrode disposed on the second surface of the crystalline silicon substrate.

A detailed description is given in the following embodiments with reference to the accompanying drawings.

### BRIEF DESCRIPTION OF THE DRAWINGS

The disclosure can be more fully understood by reading the subsequent detailed description and examples with references made to the accompanying drawings, wherein:

FIG. 1 is a schematic drawing of a crystalline silicon solar cell wafer according to an embodiment of the disclosure;

FIG. 2 is a cross section of the crystalline silicon solar cell wafer shown in FIG. 1 along the line 2-2′;

FIG. 3 is a cross section of the crystalline silicon solar cell wafer according to an embodiment of the disclosure;

FIG. 4 is a flowchart showing a method for fabricating a crystalline silicon solar cell wafer according to an embodiment of the disclosure;

FIGS. 5A to 5C are a series of cross sections showing a method for fabricating a crystalline silicon solar cell wafer according to an embodiment of the disclosure;

FIG. 6 is a cross section of the crystalline silicon solar cell wafer with a textured first surface according to an embodiment of the disclosure;

FIG. 7 is a cross section of the crystalline silicon solar cell wafer with a textured first surface and a textured second surface according to an embodiment of the disclosure;

FIG. 8 is a cross section of the crystalline silicon solar cell wafer according to another embodiment of the disclosure;

FIG. 9 is a flowchart showing a method for fabricating a crystalline silicon solar cell according to an embodiment of the disclosure;

FIGS. 10A to 10E are a series of cross sections showing a method for fabricating a crystalline silicon solar cell wafer according to an embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In an embodiment of the disclosure, a crystalline silicon solar cell wafer, and a solar cell employing the same are provided. Since the crystalline silicon solar cell wafer of the disclosure has an edge insulating structure, a solar cell prepared from the crystalline silicon solar cell wafer can be fabricated without the edge isolation process used in the fabrication of conventional solar cells. Therefore, the crystalline silicon solar cell of the disclosure has better photoelectric conversion efficiency, is less costly, and more environmentally friendly.

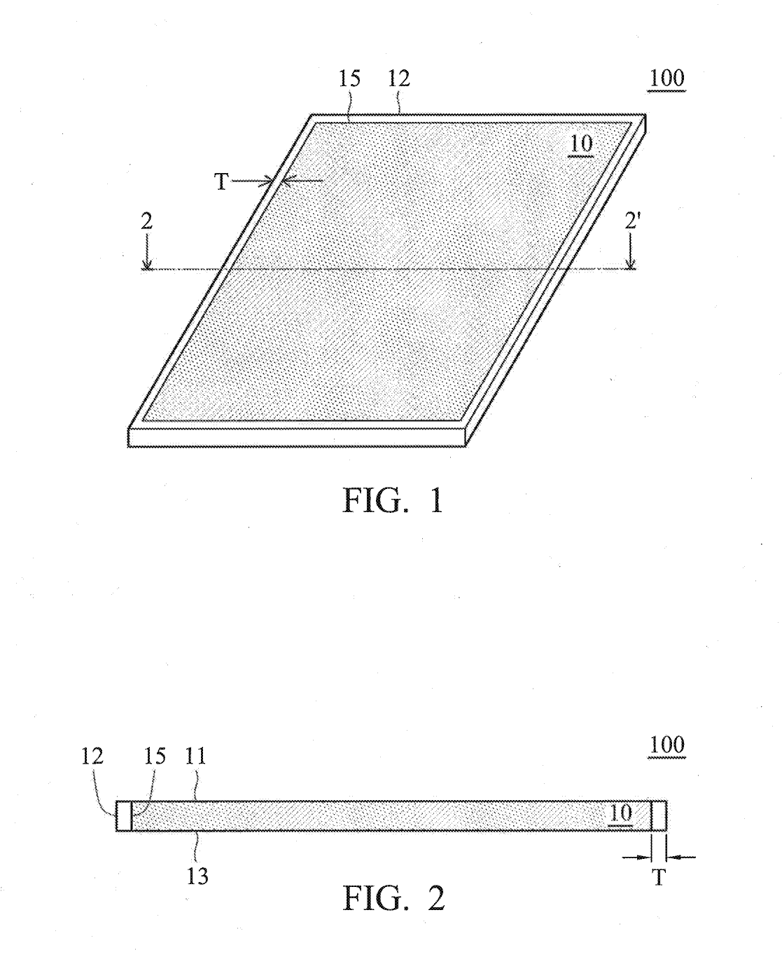

In an embodiment of the disclosure, in reference to FIG. 1, the crystalline silicon solar cell wafer 100 according to an embodiment of the disclosure, having an edge insulating structure, includes a crystalline silicon substrate 10, and an insulating layer 12. Particularly, in reference to FIG. 2 (a cross section along the line 2-2′ of FIG. 1), the crystalline silicon substrate 10 has a first surface 11, a second surface 13, and a side surface 15. The side surface 15, refers to all of the surfaces of the crystalline silicon substrate 10, except for the first surface 11 and the second surface 13. In the embodiment of FIG. 1, the side surface 15, refers to the four side walls of the quadrilateral crystalline silicon substrate 10. It should be noted that the insulating layer 12 is formed merely on the side surface 15 of the crystalline silicon substrate 10. Particularly, the entire side surface 15 of the crystalline silicon substrate 10 is covered by the insulating layer 12, and the insulating layer 12 directly contacts with the crystalline silicon substrate 10. Namely, the first surface 11 and the second surface 13 of the crystalline silicon substrate 10 are not covered by the insulating layer 12. In an embodiment of the disclosure, the crystalline silicon substrate 10 has a resistivity of between 1×10⁻⁵ and 1×10⁶ ohm·m, and has an energy gap (from the valence band to the conduction band) of between 1-3 eV. For example, the crystalline silicon substrate 10 can be a single crystalline silicon substrate, or a poly-crystalline silicon substrate. Further, the crystalline silicon substrate 10 can be an n-type doped crystalline silicon substrate or a p-type doped crystalline silicon substrate. The insulating layer 12 can have a minimum resistivity of 1×10⁸ ohm·m, and has an energy gap (from the valence band to the conduction band) of more than 9 eV. The insulating layer 12 can be a silicon-containing insulating layer. Referring to FIG. 2, the insulating layer 12 can have a single-layer structure which consists of silicon oxide, silicon nitride, or silicon oxynitride. In another embodiment of the disclosure, the insulating layer 12 can have a multi-layer structure selected from a group of silicon oxide layer, silicon nitride layer, and silicon oxynitride layer.

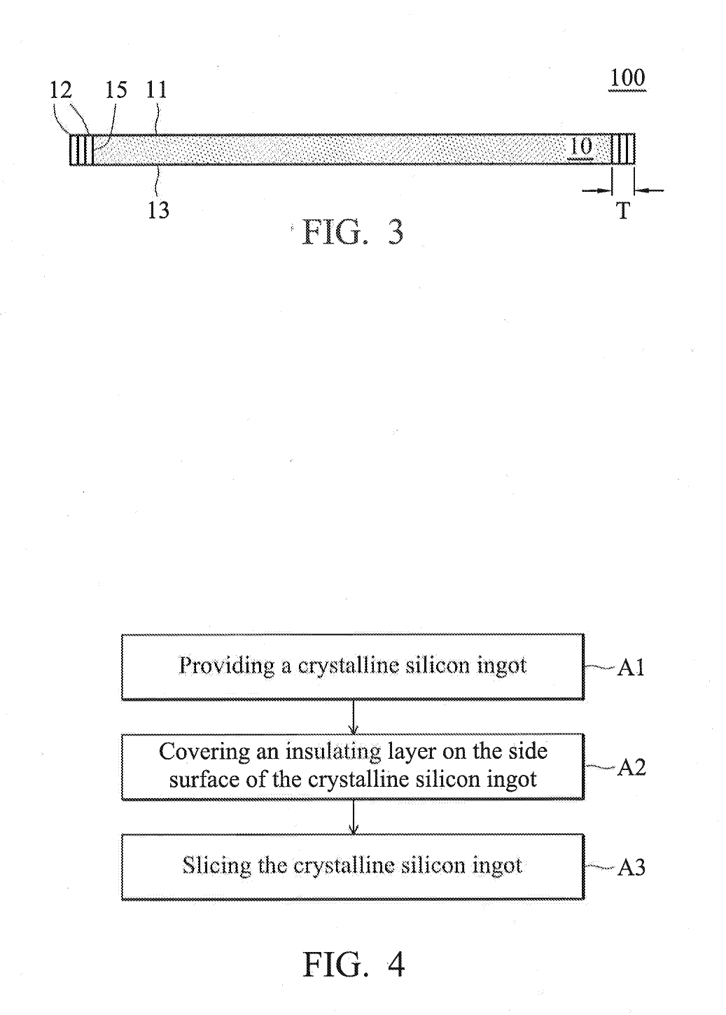

According to another embodiment of the disclosure, in reference to FIG. 3, the insulating layer 12 has a multi-layer structure including at least two layers. For example, the insulating layer 12 has a multi-layer structure selected from a group of a silicon oxide layer, silicon nitride layer, and silicon oxynitride layer. The insulating layer 12 of the disclosure can have a minimum thickness T of 45 nm, whereby the current leakage phenomenon of the solar cell does not occur. In other embodiments of the disclosure, the thickness T of the insulating layer 12 can be optionally adjusted.

In a crystalline silicon solar cell prepared from the crystalline silicon solar cell wafer 100 of the disclosure, when forming a doping layer on the crystalline silicon substrate 10, the insulating layer 12 can prevent the doping layer from forming on the side surface 15 of the crystalline silicon substrate 10. Further, since the insulating layer 12 is formed merely on the side surface 15 of the crystalline silicon substrate 10, no insulating layer 12 is directly formed on the first surface 11 and the second surface 13 of crystalline silicon substrate 10. Accordingly, the power generation area of the crystalline silicon solar cell prepared from the crystalline silicon solar cell wafer 100 is not reduced.

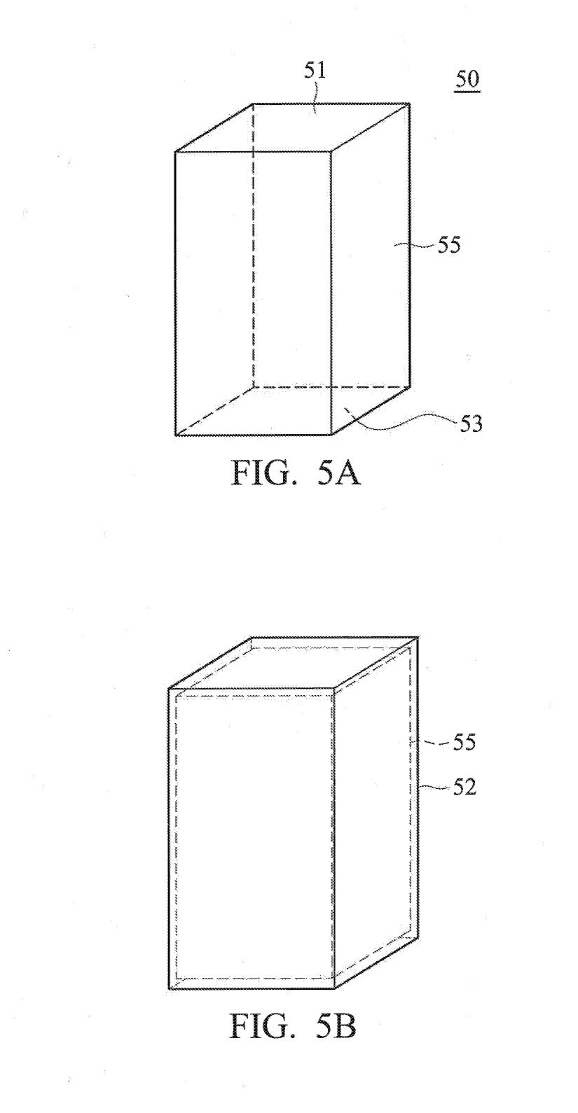

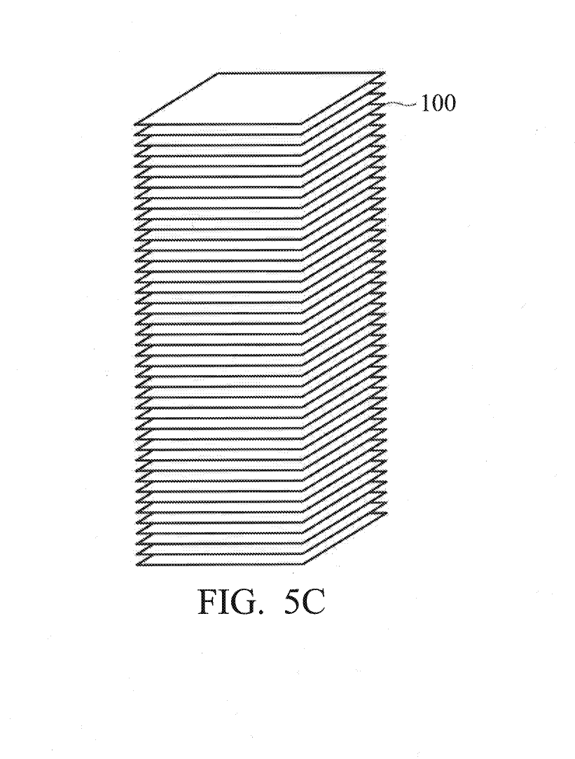

In an embodiment of the disclosure, the method for fabricating the crystalline silicon solar cell wafer 100 of FIG. 1 can include the following steps (please refer to FIG. 4). First, a crystalline silicon ingot 50 (step A1) is provided, wherein the crystalline silicon ingot 50 has a first surface 51, a second surface 53, and a side surface 55, in reference to FIG. 5A. In an embodiment of the disclosure, the crystalline silicon ingot 50 can be a cylindric crystalline silicon ingot, a polished square pillar-shaped crystalline silicon ingot, or a crystalline silicon ingot with other shapes. The crystalline silicon ingot can be a single crystalline silicon ingot, or a poly-crystalline silicon substrate. Further, the crystalline silicon ingot 50 can be a doped crystalline silicon ingot (such as an n-doped crystalline silicon ingot, or p-doped crystalline silicon ingot). Next, an insulating layer 52 is formed to cover the entire side surface 55 of the crystalline silicon ingot 50 (step A2). Alternatively, the insulating layer 52 can also be further formed on the first surface 51, and second surface 53, during formation of the insulating layer 52 to cover the side surface 55, in reference to FIG. 5B. The method for covering the insulating layer 52 to the side surface 55 of the crystalline silicon ingot 50 can include deposition, chemical vapor deposition, plasma enhanced chemical vapor deposition, atomic layer deposition, a sputtering process, thermal oxidation, a coating process, or combinations thereof. The insulating layer 52 can have a minimum resistivity of 1×10⁸ ohm·m, and have an energy gap (from the valence band to the conduction band) of about 9 eV. The insulating layer 52 can be a silicon-containing insulating layer, wherein the insulating layer 52 can have a single-layer structure consisting of silicon oxide, silicon nitride, or silicon oxynitride. In another embodiment of the disclosure, the insulating layer 52 can have a multi-layer structure. For example, the insulating layer 52 has a multi-layer structure consisting of a group of a silicon oxide layer, silicon nitride layer, and silicon oxynitride layer. The insulating layer 52 can have a minimum thickness of not less than 45 nm. In other embodiments of the disclosure, the thickness T of the insulating layer 52 can be optionally adjusted. Finally, in reference to FIG. 5C, the crystalline silicon ingot 50 covered by the insulating layer 52 on the side surface 55 is sliced (step A3), obtaining a plurality of crystalline silicon solar cell wafers 100 as shown in FIGS. 1 and 2.

Further, according to some embodiments of the disclosure, after obtaining the crystalline silicon solar cell wafer 100 as shown in FIGS. 1 and 2, at least one of the first surface 11, the second surface 13, and the side surface 15 of the crystalline silicon solar cell wafer 100 is subjected to a surface texturing process, forming a textured surface. The textured surface can reduce the reflectance of the incident light of the solar cell prepared from the crystalline silicon solar cell wafer 100.

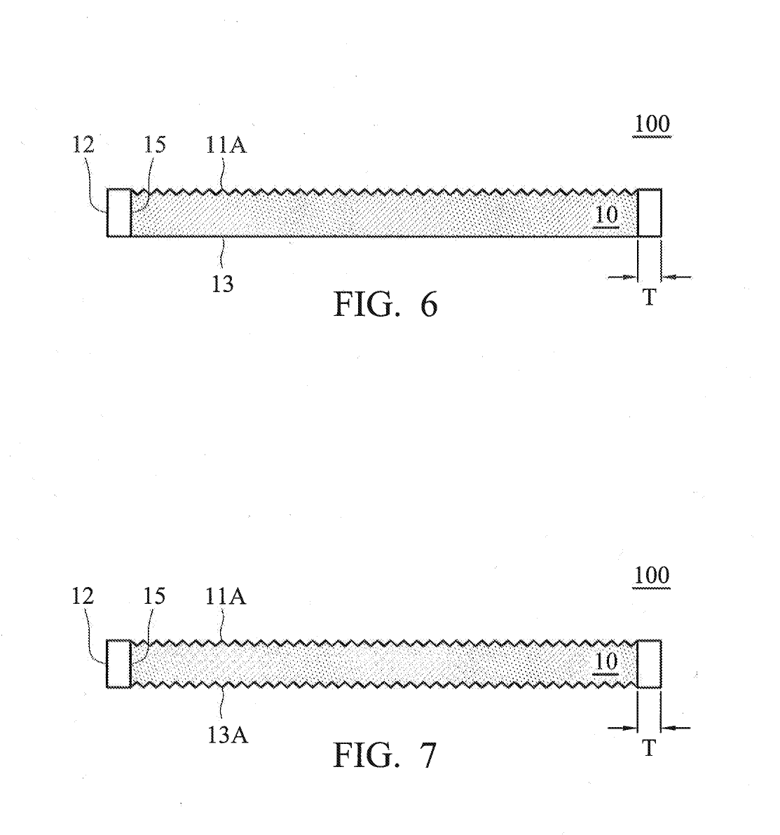

In an embodiment of the disclosure, the first surface 11 of the crystalline silicon solar cell wafer 10 can be subjected to a surface texturing process, forming a textured first surface 11A, in reference to FIG. 6. Further, according to another embodiment of the disclosure, the first surface 11 and the second surface 13 of the crystalline silicon solar cell wafer 100 can be subjected to a surface texturing process simultaneously, forming a textured first surface 11A and a second surface 13A, in reference to FIG. 7.

Accordingly, since the crystalline silicon solar cell wafer of the disclosure has an edge insulating structure, a solar cell prepared from the crystalline silicon solar cell wafer can be fabricated without the edge isolation process used in the fabrication of conventional solar cell. Therefore, the crystalline silicon solar cell of the disclosure has better photoelectric conversion efficiency, is less costly, and more environmentally friendly.

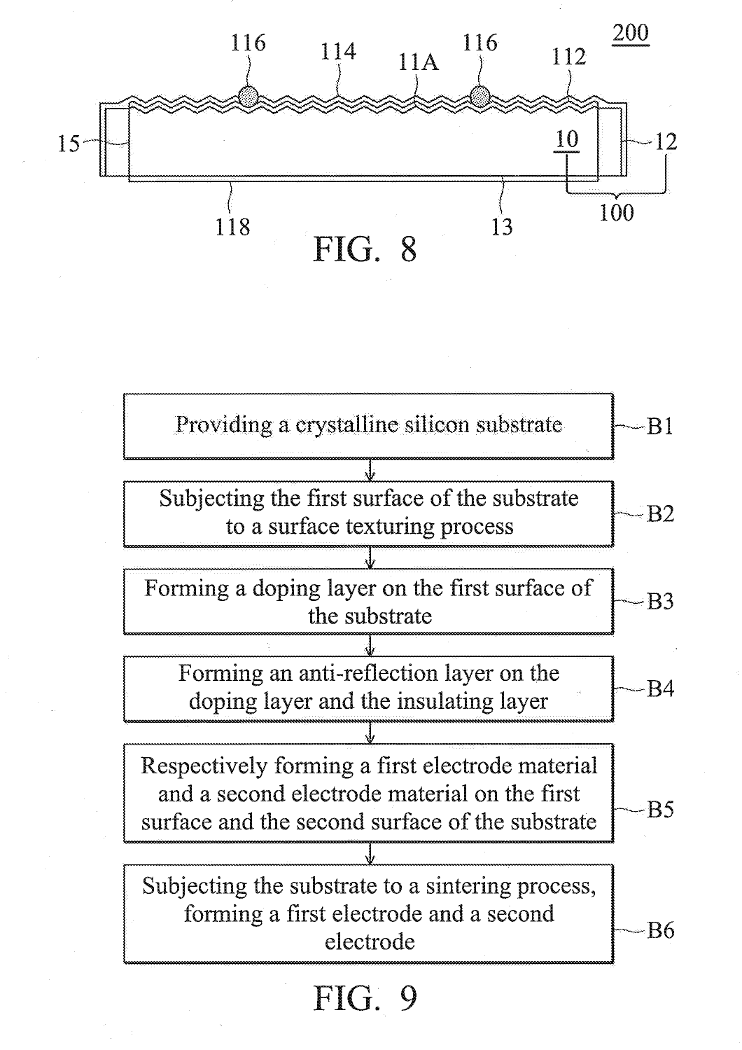

FIG. 8 is a cross section showing a crystalline silicon solar cell 200, prepared from the crystalline silicon solar cell wafer 100, according to an embodiment of the disclosure. The crystalline silicon solar cell 200 employs the crystalline silicon solar cell wafer 100 as shown in FIG. 1, wherein the crystalline silicon solar cell wafer includes a crystalline silicon substrate 10, and an insulating layer 12. The crystalline silicon substrate 10 has a first surface 11, a second surface 13, and a side surface 15, wherein the insulating layer 12 is formed merely on the side surface 15 of the crystalline silicon substrate 10.

In an embodiment of the disclosure, the first surface 11 of the crystalline silicon substrate 10 can be a textured first surface 11A (as shown in FIG. 8), in order to reduce the reflectance of the incident light and efficiently collect the incident light. Further, the crystalline silicon substrate can have a resistivity of between 1×10⁻⁵ and 1×10⁶ ohm·m, and have an energy gap (from the valence band to the conduction band) of between 1-3 eV. For example, the crystalline silicon substrate 10 can be a single crystalline silicon substrate, or a poly-crystalline silicon substrate. The crystalline silicon substrate 10 can be a doped crystalline silicon substrate having a first conductivity type, such as an n-type doped crystalline silicon substrate or a p-type doped crystalline silicon substrate. The insulating layer 12 can be silicon-containing insulating layer, in reference to FIG. 2. The insulating layer 12 can have a single-layer structure consisting of silicon oxide, silicon nitride, or silicon oxynitride. According to another embodiment of the disclosure, in reference to FIG. 3, the insulating layer 12 can have a multi-layer structure selected form a group of a silicon oxide layer, silicon nitride layer, and silicon oxynitride layer.

A doping layer 112 (having a second conductivity type) is formed on the first surface 11 of the crystalline silicon substrate 10. Namely, the doping layer 112 is not further formed on the side surface 15, or the second surface 13 of the crystalline silicon substrate. The doping layer 112 can be a doped crystalline silicon layer, which has the second conductivity type opposite to the first conductivity type of the crystalline silicon substrate 10. For example, the doping layer 112 can be a p-type doping layer (such as a boron-doped crystalline silicon), when the crystalline silicon substrate 10 is an n-type doped crystalline silicon substrate. To the contrary, the doping layer 112 can be an n-type doping layer (such as a phosphor-doped crystalline silicon), when the crystalline silicon substrate 10 is a p-type doped crystalline silicon substrate. Therefore, the crystalline silicon substrate 10 and the doping layer 112 comprise a p-n junction.

An anti-reflection layer 114 is formed on the doping layer 112, and the insulating layer 12, in order to reduce the reflectance of the incident light. For example, the anti-reflection layer 114 can be a silicon nitride layer. Further, the material of the anti-reflection layer 114 can be the same as the material of the insulating layer 12. A first electrode 116 (including Ag, Al, or alloy thereof) is disposed on the anti-reflection layer 114, wherein the first electrode 116 passes through the anti-reflection layer 114 to electrically contact with the doping layer 112. A second electrode 118 (such as an Al—Si alloy) is disposed on the second surface 13 of the crystalline silicon substrate 10, wherein the second electrode 118 directly contacts with the crystalline silicon substrate 10. It should be noted that, the insulating layer 12 of the crystalline silicon solar cell 200 covers the entire side surface 15 of the crystalline silicon substrate 10, and the insulating layer 12 directly contacts with the crystalline silicon substrate 10. Therefore, the doping layer 112 is separated from the side surface 15 of the crystalline silicon substrate 10 by the insulating layer 12, whereby the doping layer 112 does not directly contact with the side surface 15 of the crystalline silicon substrate 10.

According to an embodiment of the disclosure, a method for fabricating the crystalline silicon solar cell 200 can include the following steps, in reference to FIG. 9. First, a crystalline silicon solar cell wafer 100 is provided (step B1), wherein the crystalline silicon solar cell wafer 100 includes a crystalline silicon substrate 10 (having a first surface 11, a second surface 13, and a side surface 15), and an insulating layer 12 formed merely on the side surface 15 of the crystalline silicon substrate 10, in reference to FIGS. 1 and 2.

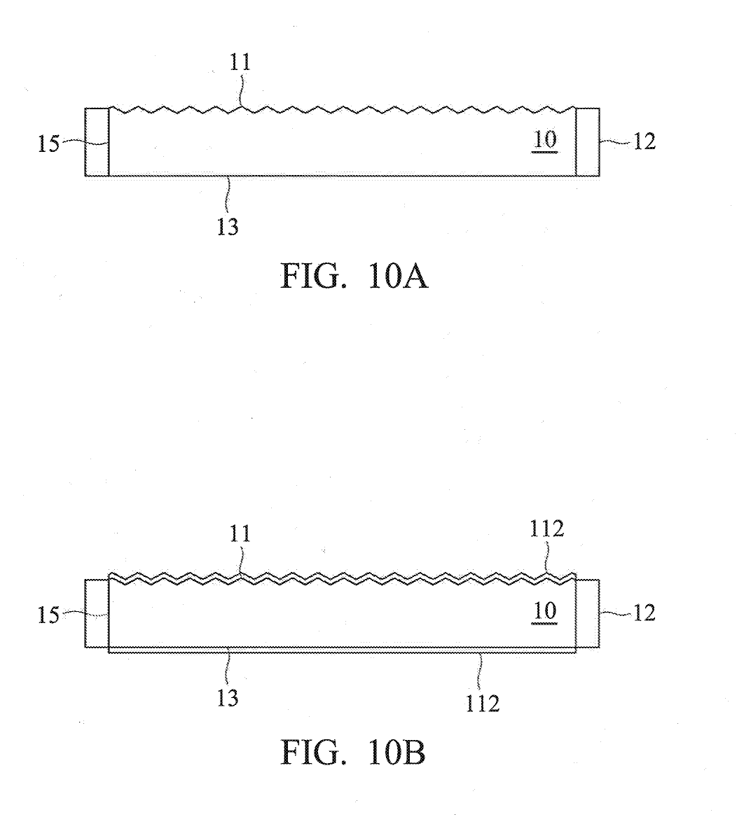

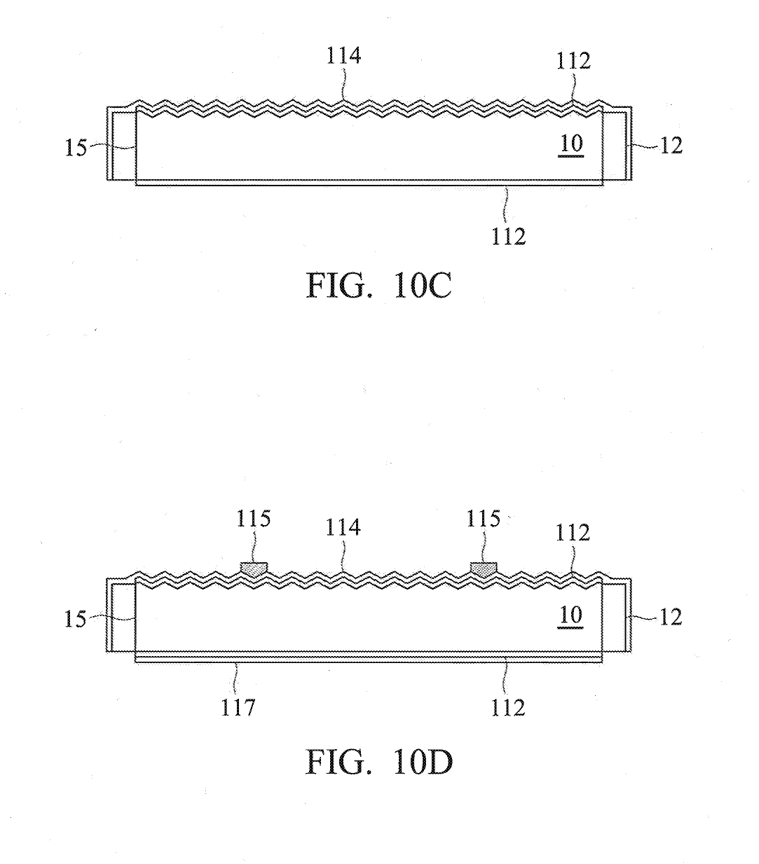

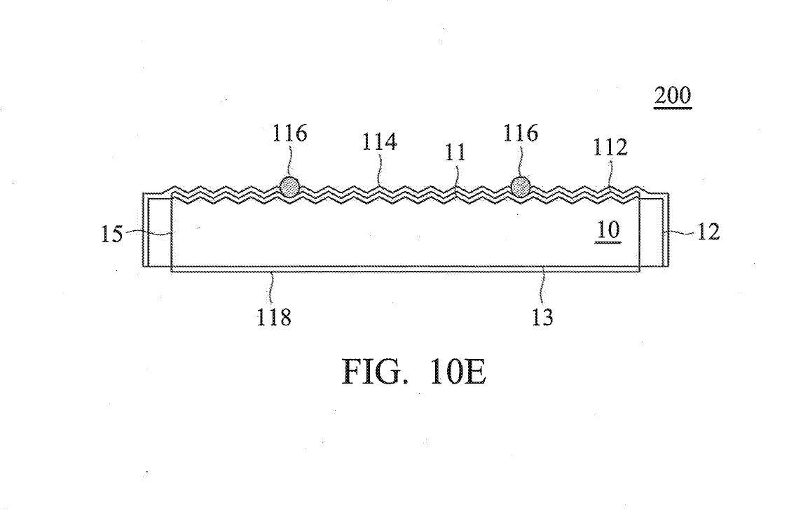

Next, the first surface 11 of the crystalline silicon solar cell wafer is subjected to a surface texturing process (step B2), in reference to FIG. 10A. In an embodiment of the disclosure, the surface texturing process includes roughening the first surface 11 of the crystalline silicon substrate 10 by acid etching, thereby reducing the reflectance of incident light. In another embodiment of the disclosure, at least one of the first surface 11, the second surface 13, and the side surface 13 is subjected to a surface texturing process.

Next, a doping layer 112 is formed on the first surface 11 of the crystalline silicon substrate 10 (step B3), in reference to FIG. 10B. In an embodiment of the disclosure, the crystalline silicon substrate 10 can be an n-type doped crystalline silicon substrate, and the method for forming the doping layer 112 includes placing the crystalline silicon substrate 10 into a furnace, and introducing boron-containing gas therein, wherein the boron atoms diffuses into the surface of the crystalline silicon substrate 10 to form a p-type doping layer 112. According to another embodiment of the disclosure, the crystalline silicon substrate 10 can be a p-type doped crystalline silicon substrate, and the method for forming the doping layer 112 includes placing the crystalline silicon substrate 10 into a furnace, and introducing phosphor-containing gas therein, wherein the phosphor atoms diffuses into the surface of the crystalline silicon substrate 10 to form an n-type doping layer 112.

It should be noted that, in the method for fabricating the crystalline silicon solar cell 200, since the entire side surface 15 of the crystalline silicon substrate 10 is covered by the insulating layer 12 (as shown in FIGS. 1 and 2) before forming the doping layer 112 on the crystalline silicon substrate 10, the side surface 15 of the crystalline silicon substrate 10 does not form as part of the doping layer 112 during the formation of the doping layer.

Next, an anti-reflection layer 114 is formed on the doping layer 112 and the insulating layer 12 (step B4), in reference to FIG. 10C. In an embodiment of the disclosure, the method for forming the anti-reflection layer 114 can include placing the structure of FIG. 10B into a furnace, and depositing a silicon nitride anti-reflection layer 114 on the doping layer 112 and the insulating layer 12 by plasma enhanced chemical vapor deposition in an atmosphere containing SiH4 and ammonia. In an embodiment of the disclosure, the material of the anti-reflection layer 114 is the same as the material of the insulating layer 12. For example, the anti-reflection layer 114 and the insulating layer 12 are made of silicon nitride.

Next, a first electrode material 115 and a second electrode material 117 are formed respectively on the first surface 11 and the second surface 13 of the crystalline silicon substrate 10 (step B5), in reference to FIG. 10D. In an embodiment of the disclosure, the first electrode material 115 can be formed on the anti-reflection layer 114 by screen-printing of a silver paste and/or an aluminum paste, and, the second electrode material 115 can be formed on the second surface 13 of the crystalline silicon substrate 10 by screen-printing of an aluminum paste.

Finally, the structure of FIG. 10D is subjected to a sintering process (step B6), forming a first electrode 116 which passes through the anti-reflection layer 114 and contacts with the doping layer 112. Further, in the sintering process, the second electrode material 117 and the doping layer formed on the second surface 13 of the crystalline silicon substrate 10 are alloyed to form an Al—Si alloy serving as a second electrode 118, in reference to FIG. 10E, thus completing the process for fabricating the crystalline silicon solar cell 200. Particularly, the area of the first surface 11 of the crystalline silicon substrate 10 is a constant during the method for fabricating the crystalline silicon solar cell 200.

It should be noted that, in the fabrication of the conventional solar cell, since the doping layer also covers the side surface of the silicon substrate, an additional edge isolation cutting process is performed to remove the edge region (adjacent to the original side surface of the substrate) of the crystalline silicon substrate 10 after formations of the anti-reflection layer, the first electrode, and the second electrode, in order to prevent current leakage between the first electrode and the second electrode at the edge region of the substrate. In comparison with the fabrication of the conventional solar cell, since the solar cell of the disclosure is prepared from a crystalline silicon substrate having an insulating layer covering the side surface of the substrate, a subsequently formed doping layer does not directly cover the side surface of the substrate. Therefore, the edge isolation cutting process can be omitted during the fabrication of the conventional solar cell of the disclosure. Accordingly, the fabrication of the crystalline silicon solar cell of the disclosure has the following advantages. (1) The edge isolation cutting process can be omitted in the fabrication of the solar cell of the disclosure, resulting in increased throughput, lowered manufacturing costs, and reduced pollutants. (2) In the fabrication of the solar cell of the disclosure, since the edge region of the substrate is not removed, the power generation area of the solar cell of the disclosure is increased by about 1.3% in comparison with the conventional solar cell. (3) Since the substrate can be prevented from being damaged (such as breakage) due to the edge isolation cutting process, the solar cell of the disclosure has better yield. (4) Since the current leakage between the first electrode and the second electrode at the edge region of the substrate is prevented, the solar cell of the disclosure has better operational safety.

The following examples are intended to illustrate the disclosure more fully without limiting its scope, since numerous modifications and variations will be apparent to those skilled in this art.

### Fabrication of the Crystalline Silicon Solar Cell Wafer with the Insulating Layer

### Example 1

Three crystalline silicon solar cell wafers (obtained by slicing a crystalline silicon ingot) were stacked together and placed into a plasma enhanced chemical vapor deposition chamber. Next, a silicon nitride layer was formed on the stack at 450□ for 700 s under vacuum. Next, the stack was removed from the chamber, wherein the lowest two crystalline silicon solar cell wafers of the stack had the structure as shown in FIGS. 1 and 2. Next, the lowest two crystalline silicon solar cell wafers of the stack were measured to determine the thickness T of the insulating layer (silicon nitride layer) formed on the silicon nitride of the wafer, and the thickness T was 50 nm.

The thickness T of the insulating layer can be modified by prolonging or shortening the deposition duration. However, it would take too long (more than 7,000 s) to form a silicon nitride insulating layer with a thickness of 1 μm. Therefore, a composite insulating layer can be formed on the side surface of the wafer, wherein the composite insulating layer can include an inner insulating layer, formed by PECVD, directly covering the side surface of the wafer, and an outer insulating layer, formed by coating, directly covering the inner insulating layer. For example, the composite insulating layer can have a thickness of than 200 μm. Further, the thickness of the composite insulating layer can be optionally adjusted.

### Fabrication of the Crystalline Silicon Solar Cell

### Example 2

First, the crystalline silicon solar cell wafer with the insulating layer of Example 1 was provided, wherein the wafer had a p-type conductivity. Next, the first surface of the wafer was subjected to a surface texturing process, forming a textured first surface. Next, the crystalline silicon solar cell wafer with the insulating layer was placed into a furnace, and then heated in the present of a phosphor-containing gas, resulting in that the part of the wafer adjacent to the first surface and second surface thereof was converted to a doping layer. Since the side surface was covered by the insulating layer, the part of the wafer adjacent to the side surface did not be converted to the doping layer. Next, an anti-reflection layer (made of silicon nitride) was formed on the doping layer on the first surface of the wafer, and the insulating layer by plasma enhanced chemical vapor deposition.

Next, an aluminum paste was coated on the anti-reflection layer and the doping layer on the second surface of the wafer by screen-printing respectively. Finally, the wafer was subjected to a sintering process, forming a first electrode (passing through the anti-reflection layer and contacting with the doping layer on the first surface of the wafer), and a second electrode (Al—Si alloy) directly contacting with the second surface of the wafer.

Shunt Resistivity

The shunt resistivity (Rshunt) of the solar cell of Example 2 was measured, and the results showed the solar cell of Example 2 having a Rshunt of more than 100 ohm. To the contrary, a conventional crystalline silicon solar cell fabricated without the edge isolation cutting process had a shunt resistivity of about 0.5 ohm.

Accordingly, although the solar cell of the disclosure was fabricated without the edge isolation cutting process, the solar cell of the disclosure exhibited high shunt resistivity.

It will be apparent to those skilled in the art that various modifications and variations can be made to the disclosed methods and materials. It is unintended that the specification and examples be considered as exemplary only, with a true scope of the disclosure being indicated by the following claims and their equivalents.

What is claimed is:

1. A crystalline silicon solar cell wafer, comprising:
a crystalline silicon substrate, wherein the crystalline silicon substrate has a first surface, a second surface, and a side surface; and
an insulating layer formed merely on the side surface of the crystalline silicon substrate.

2. The crystalline silicon solar cell wafer as claimed in claim 1, wherein the insulating layer covers merely on entire the side surface of the crystalline silicon substrate, and the insulating layer directly contacts with the crystalline silicon substrate.

3. The crystalline silicon solar cell wafer as claimed in claim 1, wherein the crystalline silicon substrate is a single crystalline silicon substrate, or a poly-crystalline silicon substrate.

4. The crystalline silicon solar cell wafer as claimed in claim 1, wherein the crystalline silicon substrate is an n-doped crystalline silicon substrate, or a p-doped crystalline silicon substrate.

5. The crystalline silicon solar cell wafer as claimed in claim 1, wherein the insulating layer has a resistivity of not less than 1×10⁸ ohm·m.

6. The crystalline silicon solar cell wafer as claimed in claim 1, wherein the insulating layer is a silicon-containing insulating layer.

7. The crystalline silicon solar cell wafer as claimed in claim 1, wherein the insulating layer has a single-layer structure consisting of silicon oxide, silicon nitride, or silicon oxynitride.

8. The crystalline silicon solar cell wafer as claimed in claim 1, wherein the insulating layer has a multi-layer structure selected from a group of silicon oxide layer, silicon nitride layer, and silicon oxynitride layer.

9. The crystalline silicon solar cell wafer as claimed in claim 1, wherein the insulating layer has a thickness of not less than 45 nm.

10. The crystalline silicon solar cell wafer as claimed in claim 1, wherein at least one of the first surface, the second surface, and the side surface is a textured surface.

11. A crystalline silicon solar cell, comprising:
a crystalline silicon substrate, wherein the crystalline silicon substrate has a first surface, a second surface, and a side surface, wherein the crystalline silicon substrate has a first conductivity;
an insulating layer formed merely on the side surface of the crystalline silicon substrate;
an anti-reflection layer disposed on the first surface of the crystalline silicon substrate;
a doping layer disposed between the first surface of the crystalline silicon substrate and the anti-reflection layer, wherein the doping layer has a second conductivity;
a first electrode disposed on the anti-reflection layer, wherein the first electrode passes through the anti-reflection layer to electrically contact with the doping layer; and
a second electrode disposed on the second surface of the crystalline silicon substrate.

12. The crystalline silicon solar cell as claimed in claim 11, wherein the insulating layer covers entire the side surface of the crystalline silicon substrate and directly contacts with the crystalline silicon substrate.

13. The crystalline silicon solar cell as claimed in claim 11, wherein the insulating layer has a resistivity of not less than 1×10⁸ ohm·m.

14. The crystalline silicon solar cell as claimed in claim 11, wherein the insulating layer silicon-containing insulating layer.

15. The crystalline silicon solar cell as claimed in claim 11, wherein the insulating layer has a single-layer structure consisting of silicon oxide, silicon nitride, or silicon oxynitride.

16. The crystalline silicon solar cell as claimed in claim 11, wherein the insulating layer has a multi-layer structure selected from a group of silicon oxide layer, silicon nitride layer, and silicon oxynitride layer.

17. The crystalline silicon solar cell as claimed in claim 11, wherein the insulating layer has a thickness of not less than 45 nm.

18. The crystalline silicon solar cell as claimed in claim 11, wherein the doping layer merely covers the first surface of the crystalline silicon substrate.

19. The crystalline silicon solar cell as claimed in claim 11, wherein the anti-reflection layer is separated from the side surface of the crystalline silicon substrate by the insulating layer.

20. The crystalline silicon solar cell as claimed in claim 11, wherein the crystalline silicon substrate is an n-type crystalline silicon substrate, and the doping layer is a p-type doping layer.

21. The crystalline silicon solar cell as claimed in claim 11, wherein the crystalline silicon substrate is a p-type crystalline silicon substrate, and the doping layer is an n-type doping layer.

22. The crystalline silicon solar cell as claimed in claim 11, wherein the material of the anti-reflection layer is the same as the material of the insulating layer.

23. The crystalline silicon solar cell as claimed in claim 11, wherein the second electrode does not contact with the insulating layer.
